(19) United States
(12) Patent Application Publication
(10) Pub. No.: US 2001/0016433 A1
(43) Pub. Date: Aug. 23, 2001

(54) Contact element

(75) Inventor: Norbert Pieper, Olfen (DE)

Correspondence Address: Clarence A. Green, PERMAN & GREEN, LLP, 425 Post Road, Fairfield, CT, 06430, US

(73) Assignee: Nokia Mobile Phones Ltd.

(21) Appl. No.: 09/742,784

(22) Filed: Dec. 20, 2000

(30) Foreign Application Priority Data
Dec. 28, 1999 (DE) 19963406.8

(51) Int. Cl. H05K 1/00; H01R 12/00

(52) U.S. Cl. 439/66; 439/91

(57) ABSTRACT

The invention relates to the design of non-aging contact elements 10 that establish a conductive connection between two opposing contacts in the compressed state. Contact elements 10 according to the background of the invention are generally rectangular, on the surface of which there are a number of conductors 15. As the bodies 11 of such contact elements 10 are made of foamed or vulcanized plastic to provide elasticity, they are subject to aging and therefore cannot ensure a permanent connection. For this reason a contact element 10 is specified according to the invention whose body 11 is formed only by a thin wall 12 that does not necessarily completely encircle a hollow space 13 enclosed by the body 11. This guarantees long-term stability, especially when the wall 12 is made of metal or a fiberoptic material. The same results can then be achieved when the body 11 is equipped with thin inserts 22 made of metal or optical fiber.

### FIELD OF THE INVENTION

The invention relates to the design of non-aging contact elements that form a conductive connection between two opposing contacts in the compressed state.

### BACKGROUND OF THE INVENTION

Contact elements corresponding to the generic term in claim 1 are known to the technician and have been used in large quantities to form conductive connections for a long time.

These contact elements, also referred to using the term “conductive rubber”, generally have a rectangular body on the surface of which there are a number of conductors. The body is formed entirely from a foamed or vulcanized plastic to ensure that the body can be elastically deformed when force is applied.

If on a circuit board a row of contacts having a number of contacts located next to each other is to be electrically connected to a row of contacts of a component, for example, then the contact element is first placed on the row of contacts on the circuit board, whereby the conductors on the contact element make contact with the contacts on the circuit board. Then the component with its row of contacts is placed on the contact element so that its contacts make physical contact with the conductors of the contact element. In order to ensure a certain durability of the contact produced in this manner, the height of the contact element when it is in its original state is reduced. This can be done, for example, by lightly pressing the component against the circuit board after it has been placed on the contact element and securing it in this state. If this state is reached and the contact element is clamped between the rows of contacts on the circuit board and component, then the restoring force with which the contact element attempts to assume its height and form when in its original state causes the conductors of the contact element to be pressed against the rows of contacts on the circuit board and component. To achieve the required elasticity and/or ability to store energy, the known contact elements and/or the material used for the body generally have very low expansion energy coefficients. This coefficient is the product of the tensile strength and the fracture elongation. When silicone rubber, which has a tensile strength of approximately 0.49 N/mm² and a fracture elongation of 200%, is used as the body material, then the value of this coefficient, which specifies the ability to store energy, is 98.

Even though this type of contact quick and easy to make, it turns out that such electrical connections only have a limited long-term stability. In particular, it has been determined that the conductive connections made using the contact elements described above do not guarantee a secure contact anymore when subject to environmental influences and variable climatic conditions. Possible reasons for this are that the material may harden and structural changes may arise due to the conditions and influences mentioned.

That is why the invention is the result of the task of specifying a contact element that possesses the necessary long-term stability while still making it quick and easy to connect rows of contacts.

### SUMMARY OF THE INVENTION

This task is accomplished using the features specified in claim 1. Advantageous extensions and expansions of the invention can be obtained in claims 2 through 5. A method for manufacturing a contact element is specified in claim 6. The features according to claim 7 have a different design that also accomplishes the task.

If the body 11 is formed only by a thin wall that does not necessary completely encircle the hollow space 13 enclosed by the body, then it is ensured that the required elasticity of the body is determined primarily by the thickness of the wall and the three-dimensional shape of the body. However, this does not mean that the properties of the material from which the body or wall is made are entirely insignificant. In contrast to the background of the invention, the material from which the walls are made must have the ability to store a large quantity of deformation energy per unit of volume to ensure that sufficient spring force or clamping force is provided in view of the necessary path of deformation in spite of the fact that the elasticity of the body is determined by the relatively thin wall. According to the experiences of the applicant, the “block” design of the contact elements according to the background of the invention and the material properties needed to produce the required elasticity are responsible for the fact that the contact elements manufactured in this manner have only a limited long-term stability. In more precise terms, the lack of long-term stability of the known contact elements can be attributed to the fact that the material used is subject to shrinkage, amongst other things. If, for example, a foamed material is used for the elastic body, gas bubbles embedded in the body diffuse into the environment after a while, thereby reducing the original spatial dimensions of the contact element at the same time. This shrinkage is responsible for the fact that the force with which a contact element clamped between a circuit board and a component is pressed against the rows of contacts on the component and circuit board is reduced or that the previously existing contact is broken.

However, if in accordance with the invention the body of the contact element is formed only by a thin wall and the required elasticity is achieved through the three-dimensional shape and thickness of the wall, then materials used in “block” designs that also display elasticity do not have to be used, thereby simultaneously reducing or completely eliminating the shrinkage problem. If one uses thin-walled optical fiber or an optical fiber composite material, for example, whereby the overall elastic properties are primarily due to the optical fiber, then neither slow reorientation of the structure of the material nor chemically induced material changes can arise because glass as a material is resistant to these effects. Another surprising result in this context is that materials can be used whose expansion energy coefficients are significantly higher than the values stated in the background of the invention. In order to clarify this here we would like to point out that coefficients greater than 2800 result when fiberoptic materials are used that have tensile strengths greater than 2400 N/mm² and a fracture elongations of about 1.2%.

As stated in claim 2, there are no restrictions placed on the design of the walls. In addition to the solid design of the wall, the use of braided materials is particularly advantageous when the flexural elasticity resulting from a solid design is to be further increased, for example.

There are also no major restrictions when selecting the type of material, as stated in claim 3, as long as the material used has a certain flexural elasticity.

If in accordance with claim 4 an intermediate layer is used between wall and conductors, then this layer may smooth out any irregularities existing on the surface of the wall or on the surfaces of the conductors. The intermediate layer can also be used as all electrical insulator in addition to its smoothing function when the wall is made of a nonconductive material.

There is a defined contact surface, and therefore a defined contact resistance, when there are tabs on the two opposing areas of the wall that exist to establish contact between the corresponding rows of contacts and that are farther from the center point of the body than the areas of the wall 12 directly adjacent to the tabs.

An especially simple method of manufacturing a contact element equipped with an intermediate layer results when the intermediate layer is designed as a tube and the wall of the body does not completely encircle the hollow space enclosed by the body. In this case it is possible to insert the compressed body into the tube. If the body has reached its end position in the tube and the force that compressed the body is removed, then the body will press against the inside of the tube and put pressure on it. It does not matter in this regard if the conductors are placed on the tube before or after connecting it to the body.

If the contact element is designed corresponding to the features in claim 7, then the same advantages already explained in the context of claim 1 exist because regardless of the material of the body, only the inserts can permanently provide the required spring force or clamping force in view of the required path of deformation due to their ability to store a large quantity of deformation energy per unit of volume.

### BRIEF DESCRIPTION OF THE DRAWINGS

The following figures contain the following:

FIG. 1 A perspective diagram of a contact element;

FIG. 2 Another contact element in a diagram according to FIG. 1;

FIG. 3 An assembly situation with a side view of two contact elements;

FIG. 4 A side view of a contact element;

FIG. 5 A side view of a contact element;

FIG. 6 Another contact element in a diagram according to FIG. 5;

FIG. 7 Another contact element in a diagram according to FIG. 4 and

FIGS. 8a-e Side views of five additional contact elements.

### DETAILED DESCRIPTION OF THE PREFERRED EMBODIMENTS OF THE INVENTION

The invention will now be explained in more detail based on the figures.

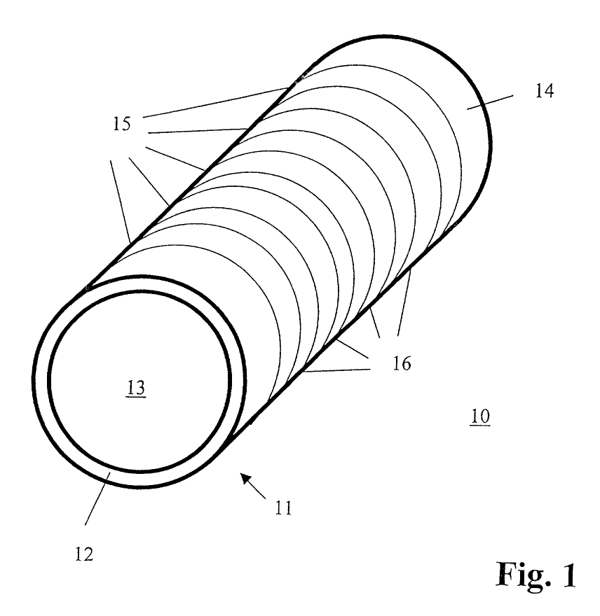

FIG. 1 shows a contact element 10 in a perspective diagram. The body 11 of this contact element 10 is formed in this case by a thin wall 12 that completely encircles the hollow space 13 enclosed by the body 11. The outer surface 14 of this body 11 is equipped with circumferential conductors 15 that are electrically isolated from each other due to the distances 16 from each other. These conductors 15 can be manufactured by vapor depositing a thin layer of metal onto the outer surface 14, for example.

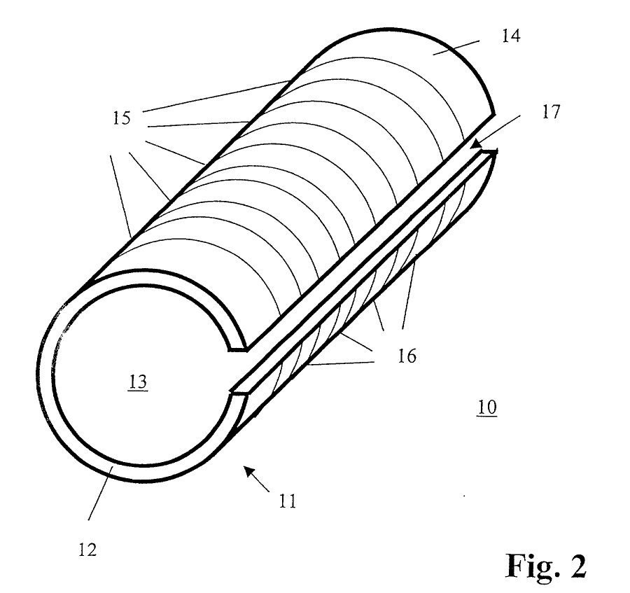

The contact element 10 shown in FIG. 2 essentially corresponds to the contact element 10 shown in FIG. 1. The body 11 of the contact element 10 is formed by a thin wall 12 in FIG. 2 also. However, in contrast to the design according to FIG. 1, the wall 12 is equipped with a slit 17. As this slit 17 runs the entire length of the contact element 10 as can clearly be seen in FIG. 2, the wall 12 shown in FIG. 2 does not completely encircle the hollow space 13 enclosed by the body 11.

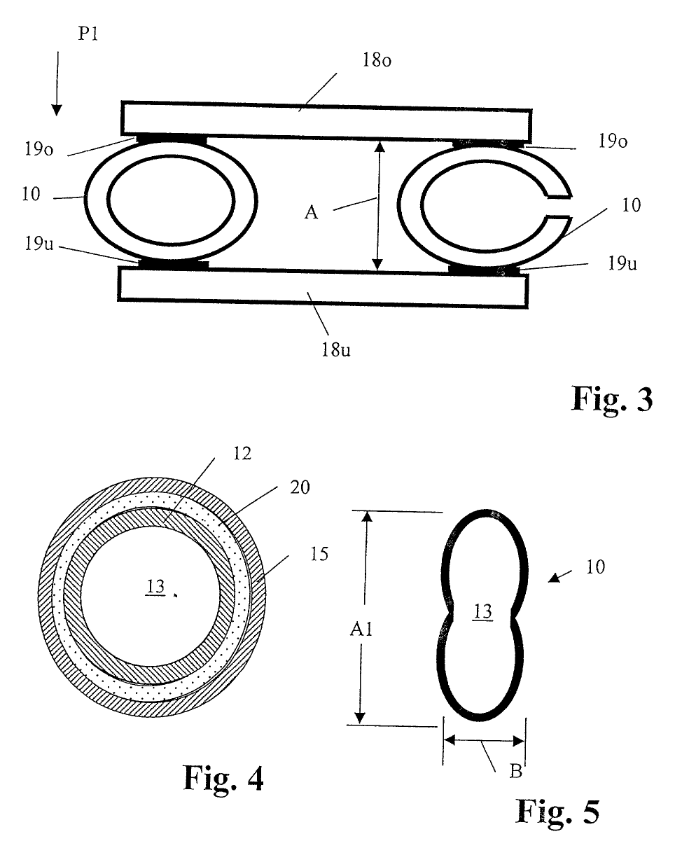

FIG. 3 shows an assembly situation for contact elements 10 in which a contact element 10 according to FIG. 1 is used on the left side and a contact element 10 according to FIG. 2 is used on the right side. In addition there is a lower and an upper circuit board 18u, 18o present, where these two circuit boards 18u, 18o are each equipped with two rows of contacts 19. Just for the sake of completeness we would like to point out that a “row of contacts” is understood to be a number of separate contacts (not visible in FIG. 3) that are isolated from each other on the corresponding circuit board 18u, 18o and that are arranged next to each other in a row perpendicular to the plane of the paper (FIG. 3). Contact between the two rows of contacts 19u on the lower circuit board 18u and the rows of contacts 19o on the upper circuit board 18o is made in such a manner that each contact element 10 is placed on a row of contacts 19u on the lower circuit board 18u first. The contact elements 10 are aligned at the same time or thereafter. It is important when doing this that the conductors 15 (not shown in FIG. 3) of the left contact element 10 come into physical contact with the contacts (not visible in FIG. 3) of the left row of contacts 19u and that the conductors 15 (not shown in FIG. 3) of the right contact element 10 come into physical contact with the contacts (not visible in FIG. 3) of the right row of contacts 19u. If this state is reached, the upper circuit board 18o is placed on the two contact elements 10. It is also important here that the contacts (not shown in FIG. 3) of the left row of contacts 19o physically touch the conductors 15 (not visible in FIG. 3) of the left contact element 10 and the contacts (not shown in FIG. 3) of the right row of contacts 18 physically touch the conductors 15 (not visible in FIG. 3) of the right contact element 10. To establish sufficiently good electrical contact between the rows of contacts 19u, 19o of the upper and lower circuit boards 18o, 18u when using the contact elements 10, it is necessary to elastically deform both contact elements 10 used in FIG. 3, which as shown in FIGS. 1 and 2 had a circular cross-section before being used to connect circuit boards 18o, 18u. This is done in accordance with FIG. 3 in that after the upper circuit board 18o has been placed on the contact elements 10, the upper circuit board 18o is moved in the direction of the arrow P1 against the resistance provided by the contact elements 10. If the upper circuit board 18o has reached the distance A shown in FIG. 3 from the lower circuit board 18u, then the resulting arrangement of the two circuit boards 18o, 18u is permanently secured (not visible in FIG. 3). Because the two formerly circular contact elements 10 now have an elliptical cross-section due to the elastic deformation through the movement of the upper circuit board 18o in the direction of the arrow P1, the restoring force built up in the contact elements 10 that works in the direction of arrow P1 ensures that the conductors 15 (not shown in FIG. 3) are pressed against the contacts (not visible in FIG. 3) on the rows of contacts 19u, 19o.

Because, in accordance with the invention, the restoring force primarily responsible for the durability of such electrical connections depends less on the material used due to the use of mostly hollow contact elements 10, a number of materials not usually used for this purpose can be utilized to form the contact elements 10. This does not mean, however, that material properties are to be completely ignored. On the contrary, it must also be insured according to the invention that the material or materials used to form the hollow contact elements 10 are elastic and can be deformed as explained in the context of FIG. 3. However, as the required elasticity is primarily provided by the hollow shape, in contrast to the background of the invention, non-aging materials can be used. For example, FIG. 4 (not shown to scale) shows a contact element 10 in which the wall 12 is made of metal. This wall 12 is equipped with an intermediate layer 20 that completely covers the outside of the wall 12. The circumferential conductors 15 are located the surface of the intermediate layer 20, which is made of an isolating material in this example, that faces away from the wall 12

Even though the wall 12 in the example according to FIG. 4 is made of metal, the design is not restricted to this material. On the contrary, wall 12 in another example (not shown) can also be made of a natural rubber or unfoamed polymer material. If the wall 12 is made of PVC material, for example, then the intermediate layer 20 used as insulation is not needed due to the insulating properties of this material.

The wall 12 does not necessarily have to be solid. Good results were also obtained with walls 12 formed from a braid of plastic, metal or fiberoptic material. If the wall 12 is formed as a braid, then the intermediate layer 20 will also provide a smoothing effect to smooth out the natural irregularities found in the surface structure, in addition to its possible insulating effect.

The contact element 10 shown in FIG. 4 can also be manufactured, for example, by forming the wall 12 first, then applying the intermediate layer, if necessary, and finally by forming the conductors 15. As can easily be realized, the steps can also be carried out in a continuous production process using the appropriate equipment so that contact elements formed only need to be separated and packaged when finished.

FIG. 5 shows a contact element 10 that has a cross-section primarily in the form of a figure eight. This contact element 10 can be used anywhere there is a large distance A1 between the rows of contacts (not shown FIG. 5) to be connected but only a limited width B to be overcome to make an electrical connection.

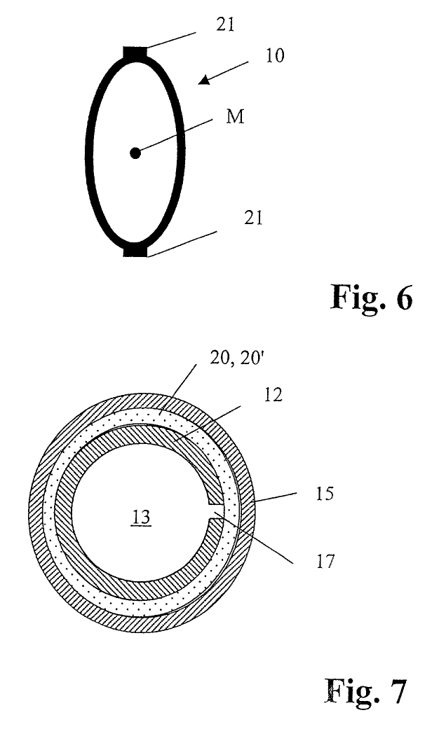

The contact element 10 shown in FIG. 6 with an elliptical cross-section will also fulfill the purpose stated in the last paragraph when it is ensured that the endpoints of the wider axis of the elliptical cross-section come into contact with the corresponding rows of contacts (not shown in FIG. 6).

In addition there are two tabs 21 shown in FIG. 6 that are farther from the center point M of the body 11 than the areas of the wall 12 directly adjacent to the tabs 21. The purpose of these tabs 21 is to establish good surface contact with the rows of contacts (not shown in FIG. 6).

For the sake of completeness, we would like to point out that the tabs 21 are not limited to contact elements 10 with elliptical cross-sections but can also be formed on contact elements according to FIGS. 1, 2, 4, 5 and 7.

FIG. 7 shows a contact element 10 in which the slit 17 is only formed in the wall 12 and not in the intermediate layer 20 and conductors 15, in contrast to the contact element 10 according to FIG. 2. A contact element 10 designed in this manner can very easily be formed by manufacturing the intermediate layer 20 as a tube 20′ and then inserting the compressed wall 12 into the tube 20′ in the direction of arrow P2. Once the wall 12 has reached its end position in the tube 20′ and the force responsible for pressing the wall 12 together is removed, the wall will press against the tube 20′ and place pressure on it. This purely mechanical connection rules out the use of complex connecting technologies required due to the different materials used for the wall and intermediate layer 12 and/or conductors 15 and also eliminates restrictions relating to the combination of materials that can be utilized. Just for the sake of completeness we would like to point out that it does not matter when performing this procedure if the conductors 15 are placed on the intermediate layer 20 or the tube 20′ before or after connecting to the wall 12.

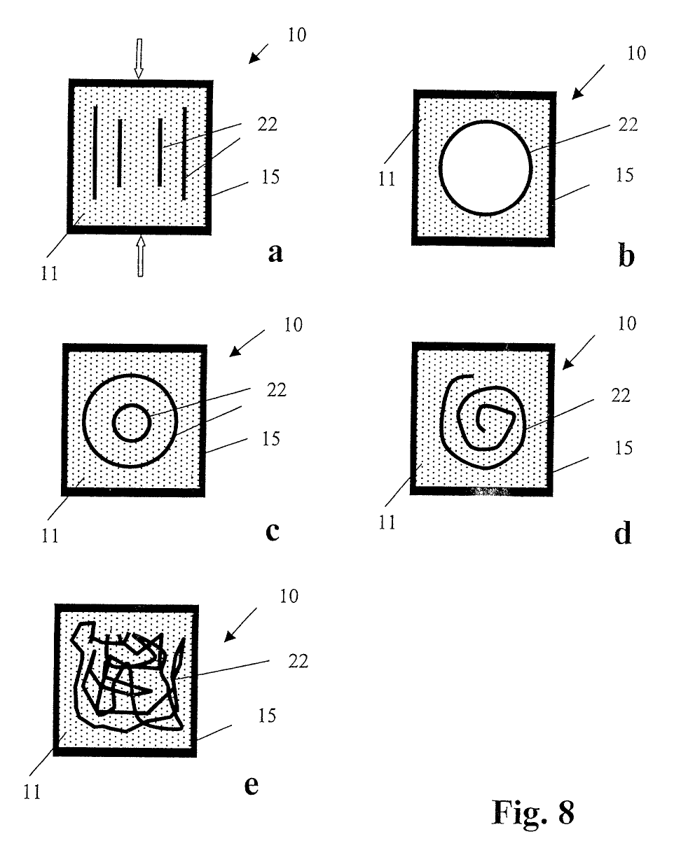

FIGS. 8a through e show side views of five examples of a contact element 10 according to claim 7. Each of these contact elements 10 has a body 11 that is encircled by a conductor 15. There is at least one insert 22 made of metal and/or fiberoptic material integrated into the interior of each body 11. In FIG. 8a the insert 22 is formed by four rectangular strips, whereby the four strips are divided into two pairs of strips of equal length. If the inserts 22 are designed as shown in FIG. 8a, then it is important for the functionality of the inserts 22 that the circuit boards (not shown FIG. 8a) come into physical contact with the contact element 10 according to the arrows.

FIGS. 8b and c show the inserts 22 in the form of circles where the contact element 10 according to FIG. 8b is equipped with one circular insert 22 and the contact element 10 according to FIG. 8c is equipped with two circular inserts 22. The insert 22 in FIG. 8d is in the form of a spiral, while FIG. 8e shows an insert 22 distributed irregularly in the body 11. As can easily be realized, it does not matter in the designs according to FIGS. 8b through d how the corresponding contact elements 10 are placed between two circuit boards (not shown) as long as it is ensured that the circuit boards come into physical contact with opposing faces of the cube-shaped contact elements 10.

Just for the sake of completeness we would like to point out that the contact elements 10 shown in FIGS. 8a through d can also be designed to have a round or oval shape.

1. Contact element
with a body 11 and
with a number of electrically conductive conductors 15 that are isolated from each other and arranged on the outer surface 14 of the body 11,
characterized in that
the body 11 is formed only by a thin wall 12 that does not necessary completely encircle the hollow space 13 enclosed by the body 11.

2. Contact element according to claim 1 characterized in that
the wall 12 is solid or formed from a braided material.

3. Contact element according to claim 2 characterized in that
the wall 12 and/or the braid is made of metal or an unfoamed plastic, in particular of a fiberoptic material.

4. Contact element according to claim 2 or claim 3 characterized in that
there is an intermediate layer 20 between the wall 12 and the conductors 15.

5. Contact element according to one of claims 1 through 4 characterized in that
there are tabs 21 formed on two areas opposite from each other on the wall 12 that are farther from the center point of the body 11 than the areas of the wall 12 directly adjacent to the tabs 21.

6. Method of manufacturing a contact element according to claim 4 characterized in that
the intermediate layer 20 is formed as a tube 20′,
the wall 12 of the body 11 does not completely encircle the hollow space 13 it encloses and
the wall 12 is to be compressed and inserted in this state into the tube 20′.

7. Contact element
with a body 11 and
with a number of electrically conductive conductors 15 that are isolated from each other and arranged on the outer surface 14 of the body 11,
characterized in that
there is at lease one thin insert 22 located within the body 11,
the corresponding insert 22 is solid or made of a braided material and
the corresponding inserts 22 are made of metal or an unfoamed plastic, in particular of a fiberoptic material.
